(19) United States
(12) Patent Application Publication
(10) Pub. No.: US 2019/0051501 A1
(43) Pub. Date: Feb. 14, 2019

(54) PLASMA PROCESSING APPARATUS

(71) Applicant: TOKYO ELECTRON LIMITED, Tokyo (JP)

(72) Inventors: Katsuyuki KOIZUMI, Miyagi (JP); Masanori TAKAHASHI, Miyagi (JP)

(73) Assignee: TOKYO ELECTRON LIMITED, Tokyo (JP)

(21) Appl. No.: 16/057,548

(22) Filed: Aug. 7, 2018

(30) Foreign Application Priority Data
Aug. 9, 2017 (JP) 2017-154746

(51) Int. Cl. H01J 37/32; H01L 21/67

(52) U.S. Cl. CPC H01J 37/32724; H01J 37/32642; H01J 2237/2001; H01J 2237/334; H01J 2237/002; H01L 21/67069

(57) ABSTRACT

Disclosed is a plasma processing apparatus including: a first member including a recessed portion in a range corresponding to a placing surface on a back surface side with respect to the placing surface on which a plasma processing target workpiece is placed; a sheet member formed in a sheet shape, including a heater and a lead wiring that supplies power to the heater, and disposed in the recessed portion such that the heater is positioned in a region corresponding to a placing surface inside the recessed portion and the lead wiring is positioned on a side surface of the recessed portion, and a second member fitted into the recessed portion in which the sheet member is disposed.

### CROSS-REFERENCE TO RELATED APPLICATIONS

This application is based on and claims priority from Japanese Patent Application No. 2017-154746 filed on Aug. 9, 2017 with the Japan Patent Office, the disclosure of which is incorporated herein in its entirety by reference.

### TECHNICAL FIELD

Various aspects and exemplary embodiments of the present disclosure relate to a plasma processing apparatus.

### BACKGROUND

In the related art, there has been known a plasma processing apparatus that performs a plasma processing (e.g., etching) on a workpiece (e.g., a semiconductor wafer) by using plasma. In such a plasma processing apparatus, a heater for temperature adjustment may be embedded in a placing table on which the workpiece is placed in order to perform a higher degree of temperature control. It is necessary to supply a power to the heater. Therefore, in the plasma processing apparatus, a power supply terminal is provided in an outer peripheral region of the placing table, and a power is supplied from the power supply terminal to the heater (see, e.g., Japanese Patent Laid-Open Publication No. 2016-001688).

### SUMMARY

According to an aspect of the present disclosure, there is provided a plasma processing apparatus having a first member, a sheet member, and a second member. The first member includes a recessed portion in a range corresponding to a placing surface on a back surface side with respect to the placing surface on which a plasma processing target workpiece is placed. The sheet member is formed in a sheet shape, includes a heater and a lead wiring that supplies power to the heater, and disposed in the recessed portion such that the heater is positioned in a region corresponding to a placing surface inside the recessed portion and the lead wiring is positioned on a side surface of the recessed portion. The second member is fitted into the recessed portion in which the sheet member is disposed.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a schematic cross-sectional view illustrating an example of a schematic configuration of a plasma processing apparatus according to an embodiment.

FIG. 2 is a schematic cross-sectional view illustrating an example of a configuration of a main part of first and second placing tables.

FIG. 3 is a schematic plan view illustrating an example of a configuration of a main part of a sheet member.

FIG. 4 is a schematic plan view illustrating an example of a region in which a heater is disposed.

FIG. 5 is a schematic plan view illustrating an example of a cross-section of a sheet member.

FIG. 6 is a schematic perspective view illustrating an example of a configuration of a main part of a second member.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made without departing from the spirit or scope of the subject matter presented here.

When a power supply terminal is provided in the outer peripheral region of the placing table, the power supply terminal is arranged outside the placing region on which the workpiece is disposed. Thus, the size in the radial direction of the placing table becomes large. The plasma processing apparatus includes a focus ring around the placing region of the workpiece. However, when the size in the radial direction of the placing table becomes large, a superposed portion of the focus ring and the outer peripheral region provided with the power supply terminal becomes large, so that non-uniformity is likely to occur in a temperature distribution in the radial direction of the focus ring. Further, in order to provide the power supply terminal in the placing table, it is required to form a through hole to pass the power supply terminal from a back surface side of the placing table. In the portion where the through hole is formed, heat conduction from the workpiece is partially deteriorated, and the portion becomes a singular point where the uniformity of heat deteriorates. Therefore, non-uniformity is likely to occur in a temperature distribution in a circumferential direction of the workpiece. In the plasma processing apparatus, when non-uniformity occurs in the temperature distribution in the workpiece or in the focus ring, the in-plane uniformity of the plasma processing on the workpiece decreases.

According to an aspect of the present disclosure, there is provided a plasma processing apparatus having a first member, a sheet member, and a second member. The first member includes a recessed portion in a range corresponding to a placing surface on a back surface side with respect to the placing surface on which a plasma processing target workpiece is placed. The sheet member is formed in a sheet shape, includes a heater and a lead wiring that supplies power to the heater, and disposed in the recessed portion such that the heater is positioned in a region corresponding to a placing surface inside the recessed portion and the lead wiring is positioned on a side surface of the recessed portion. The second member is fitted into the recessed portion in which the sheet member is disposed.

In the above-described plasma processing apparatus, the second member includes a groove or a through hole that communicates with a back surface side with respect to the recessed portion on a surface facing the side surface of the recessed portion, the sheet member includes a heater portion provided with the heater and formed to have a size of a region corresponding to the placing surface inside the recessed portion and a wiring portion provided with the lead wiring and extended from the heater portion, and the wiring portion is disposed so as to pass through the groove or the through hole of the second member.

In the above-described plasma processing apparatus, the plasma processing apparatus further includes a placing table on which a focus ring is placed along an outer peripheral surface of the first member, and the first member is formed in a cylindrical shape with the placing surface as a bottom surface.

In the above-described plasma processing apparatus, the placing table is provided with a heater provided on a placing surface on which the focus ring is placed.

In the above-described plasma processing apparatus, the second member includes a coolant flow path formed therein.

According to an aspect of the plasma processing apparatus of the present disclosure, it is possible to suppress the decrease in in-plane uniformity of plasma processing on the workpiece.

Hereinafter, embodiments of the plasma processing apparatus disclosed herein will be described in detail with reference to drawings. In addition, in the respective drawings, the same or corresponding parts will be denoted by the same symbols. Further, the present disclosure is not limited to the exemplary embodiments. The respective embodiments may be appropriately combined within a range that does not contradict the processing contents.

(Configuration of Plasma Processing Apparatus)

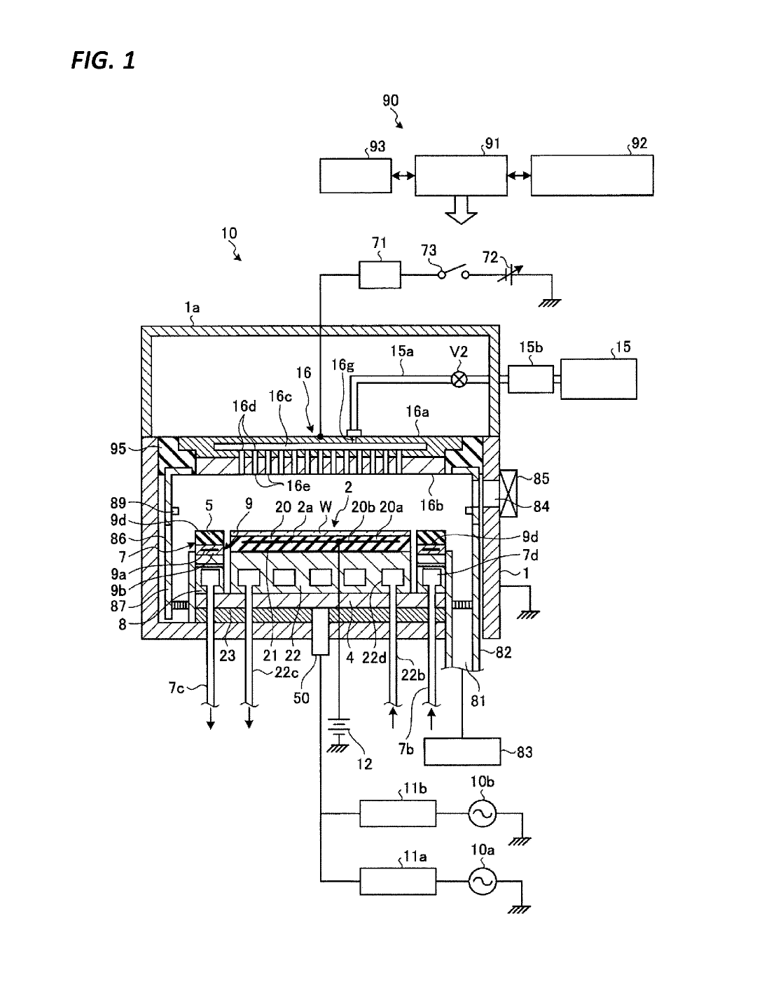

First, descriptions will be made on a schematic configuration of a plasma processing apparatus 10 according to an embodiment. FIG. 1 is a schematic cross-sectional view illustrating an example of a schematic configuration of a plasma processing apparatus according to an embodiment. The plasma processing apparatus 10 includes a processing container 1 that is airtightly constituted and electrically grounded. The processing container 1 has a cylindrical shape and is made of, for example, aluminum having an anodized film formed on the surface thereof. The processing container 1 defines a processing space in which plasma is generated. A first placing table 2 is accommodated in the processing container 1 and configured to horizontally support a semiconductor wafer (hereinafter, simply referred to as a “wafer”) which is a workpiece.

The first placing table 2 has a substantially cylindrical shape with its bottom surfaces facing upward and downward, and the upper bottom surface serves as a placing surface 2a on which the wafer W is placed. The placing surface 2a of the first placing table 2 has approximately the same size as that of the wafer W. The first placing table 2 includes a first member 20, a sheet member 21, and a second member 22.

The first member 20 is formed in a disk shape with a flat upper surface, and the upper surface serves as the placing surface 2a on which the wafer W is placed. The first member 20 includes an insulator 20a and an electrode 20b. The electrode 20b is provided inside the insulator 20a, and a DC power supply 12 is connected to the electrode 20b via a power supply mechanism (not illustrated). The first member 20 is configured to attract the wafer W by a Coulomb force when a DC voltage is applied from the DC power supply 12 to the electrode 20b. That is, the first member 20 has a function of an electrostatic chuck that attracts the wafer W.

The second member 22 is constituted by including a conductive metal, for example, aluminum. The second member 22 functions as a base that supports the first member 20 and also functions as a lower electrode. The second member 22 is supported by a RF plate which is a conductive member. The RF plate 4 is supported by the supporting stand 23 which is an insulating layer. The supporting stand 23 is provided on the bottom of the processing container 1. Further, the sheet member 21 is provided between the first member 20 and the second member 22. The sheet member 21 is provided with a heater, and is supplied with a power via a power supply mechanism (to be described later) to control the temperature of the wafer W.

The first placing table 2 is provided with a second placing table 7 around the outer peripheral surface thereof. The second placing table 7 is formed in a cylindrical shape whose inner diameter is larger than the outer diameter of the first placing table 2 by a predetermined size and is disposed coaxially with the first placing table 2. The second placing table 7 has an upper surface serving as a placing surface 9d on which an annular focus ring 5 is placed. The focus ring 5 is formed of, for example, single crystal silicon, and is placed on the second placing table 7.

The second placing table 7 includes a base 8 and a focus ring heater 9. The base 8 is made of, for example, aluminum having an anodized film formed on the surface thereof. The base 8 is supported by the RF plate 4. The focus ring heater 9 is supported by the base 8. The focus ring heater 9 has an upper surface formed in a flat annular shape, and the upper surface serves as the placing surface 9d on which the focus ring 5 is placed. The focus ring heater 9 includes a heater 9a and an insulator 9b. The heater 9a is provided inside the insulator 9b and is enclosed in the insulator 9b. The heater 9a is supplied with a power via a power supply mechanism (not illustrated) to control the temperature of the focus ring 5. In this manner, the temperature of the wafer W and the temperature of the focus ring 5 are independently controlled by different heaters.

A power supply rod 50 is connected to the RF plate 4. The power supply rod 50 is connected with a first RF power supply 10a via a first matching unit 11a and a second RF power supply 10b via a second matching unit 11b. The first RF power supply 10a is a power supply for plasma generation, and a high frequency power of a predetermined frequency is supplied from the first RF power supply 10a to the second member 22 of the first placing table 2. Further, the second RF power supply 10b is a power supply for ion drawing (bias), and a high frequency power of a predetermined frequency lower than that of the first RF power supply 10a is supplied from the second RF power supply 10b to the second member 22 of the first placing table 2.

The second member 22 includes a coolant flow path 22d formed therein. A coolant inlet pipe 22b is connected to one end of the coolant flow path 22d, and a coolant outlet pipe 22c is connected to the other end of the coolant flow path 22d. Further, the base 8 includes a coolant flow path 7d formed therein. A coolant inlet pipe 7b is connected to one end of the coolant flow path 7d, and a coolant outlet pipe 7c is connected to the other end of the coolant flow path 7d. The coolant flow path 22d is positioned below the wafer W and functions to absorb the heat of the wafer W. The coolant flow path 7d is positioned below the focus ring 5 and functions to absorb the heat of the focus ring 5. The plasma processing apparatus 10 is configured to individually control the temperatures of the first placing table 2 and the second placing table 7 by circulating a coolant (e.g., cooling water) in the coolant flow path 22d and the coolant flow path 7d, respectively. Further, the plasma processing apparatus 10 may be configured to individually control the temperatures by supplying a cold heat transfer gas to the back surface side of the wafer W or the focus ring 5. For example, a gas supply pipe for supplying a cold heat transfer gas (backside gas) (e.g., helium gas) may be provided on the rear surface of the wafer W so as to penetrate, for example, the first placing table 2. The gas supply pipe is connected to a gas supply source. With the configuration, the wafer W attracted and held on the upper surface of the first placing table 2 is controlled to a predetermined temperature.

Meanwhile, a shower head 16 having a function as an upper electrode is provided above the first placing table 2 so as to face the first placing table 2 in parallel. The shower head 16 and the first placing table 2 function as a pair of electrodes (upper and lower electrodes).

The shower head 16 is provided on a ceiling wall portion of the processing container 1. The shower head 16 includes a main body 16a and an upper ceiling plate 16b forming an electrode plate, and is supported in an upper portion of the processing container 1 via an insulating member 95. The main body 16a is made of a conductive material, for example, aluminum of which the surface is anodized, and is configured such that the upper ceiling plate 16b is detachably supported under the main body 16a.

A gas diffusion chamber 16c is provided inside the main body 16a, and a plurality of gas flow holes 16d are formed in the bottom portion of the main body 16a so as to be positioned under the gas diffusion chamber 16c. Further, gas introduction holes 16e are provided in the upper ceiling plate 16b so as to penetrate the upper ceiling plate 16b in the thickness direction and overlap with the gas flow holes 16d. With the configuration, the processing gas supplied to the gas diffusion chamber 16c is diffused in a shower form through the gas flow holes 16d and the gas introduction holes 16e and supplied into the processing container 1.

The main body 16a includes a gas introduction port 16g to introduce a processing gas to the gas diffusion chamber 16c. The gas introducing port 16g is connected with one end of a gas supply pipe 15a. The other end of the gas supply pipe 15a is connected with a processing gas supply source 15 that supplies a processing gas. In the gas supply pipe 15a, a mass flow controller (MFC) 15c and an opening/closing valve V2 are provided in order from the upstream side. A processing gas for plasma etching is supplied from the processing gas supply source 15 to the gas diffusion chamber 16c through the gas supply pipe 15a, diffused in a shower form from the gas diffusion chamber 16c through the gas flow holes 16d and the gas introduction holes 16e, and supplied into the processing container 1.

A variable DC power supply 72 is electrically connected to the shower head 16 as the upper electrode through a low pass filter (LPF) 71. The variable DC power supply 72 is configured to be able to turn on/off the power supply by an ON/OFF switch 73. The current and voltage of the variable DC power supply 72 and the ON/OFF of the ON/OFF switch 73 are controlled by a controller 90 (to be described later). Also, as described later, when high frequency waves are applied from the first RF power supply 10a and the second RF power supply 10b to the first placing table 2 and plasma is generated in a processing space, the ON/OFF switch 73 is turned on by the controller 90 as necessary so that a predetermined DC voltage is applied to the shower head 16 as the upper electrode.

In addition, a cylindrical ground conductor la is provided to extend upward from the side wall of the processing container 1 to a position higher than the height position of the shower head 16. The cylindrical ground conductor 1a has a ceiling wall in the upper portion thereof.

An exhaust port 81 is formed in the bottom portion of the processing container 1, and a first exhaust device 83 is connected to the exhaust port 81 via an exhaust pipe 82. The first exhaust device 83 includes a vacuum pump which, when operated, decompresses the interior of the processing container 1 to a predetermined degree of vacuum. Meanwhile, a carry-in/out port 84 for the wafer W is provided on a sidewall in the processing container 1, and a gate valve 85 is provided in the carry-in/out port 84 to open and close the carry-in/out port 84.

On the inner side of the side portion of the processing container 1, a deposit shield 86 is provided along the inner wall surface. The deposit shield 86 suppresses any etching byproduct (deposit) from being attached to the processing container 1. A conductive member (GND block) 89 connected to the ground in a potential-controlled manner is provided at substantially the same height position as the wafer W of the deposit shield 86. Thus, abnormal discharge is suppressed. In addition, a deposit shield 87 extended along the first placing table 2 is provided at the lower end of the deposit shield 86. The deposition shields 86 and 87 are configured to be detachable.

The operation of the plasma processing apparatus 10 having the above configuration is generally controlled by the controller 90. The controller 90 is provided with a process controller 91 that includes a CPU and controls each part of the plasma processing apparatus 10, a user interface 92, and a memory 93.

The user interface 92 includes, for example, a keyboard for inputting commands by a process manager to manage the plasma processing apparatus 10, and a display for visually displaying the operation status of the plasma processing apparatus 10.

The memory 93 stores a control program (software) for implementing various processings performed in the plasma processing apparatus 10 by the control of the process controller 91, or recipe in which, for example, a processing condition data is stored. Then, an arbitrary recipe is called from the memory 93 by, for example, an instruction from the user interface 92 as necessary, and executed by the process controller 91. Therefore, a desired processing is performed in the plasma processing apparatus 10 under the control of the process controller 91. Also, the control program or the recipe, for example, the processing condition data may be used in a state of being stored in a computer-readable computer storage medium (e.g., a hard disk, a CD, a flexible disk, or a semiconductor memory), or may be used on-line by being transmitted at any time from other devices through, for example, a dedicated line.

[Configuration of First and Second Placing Tables]

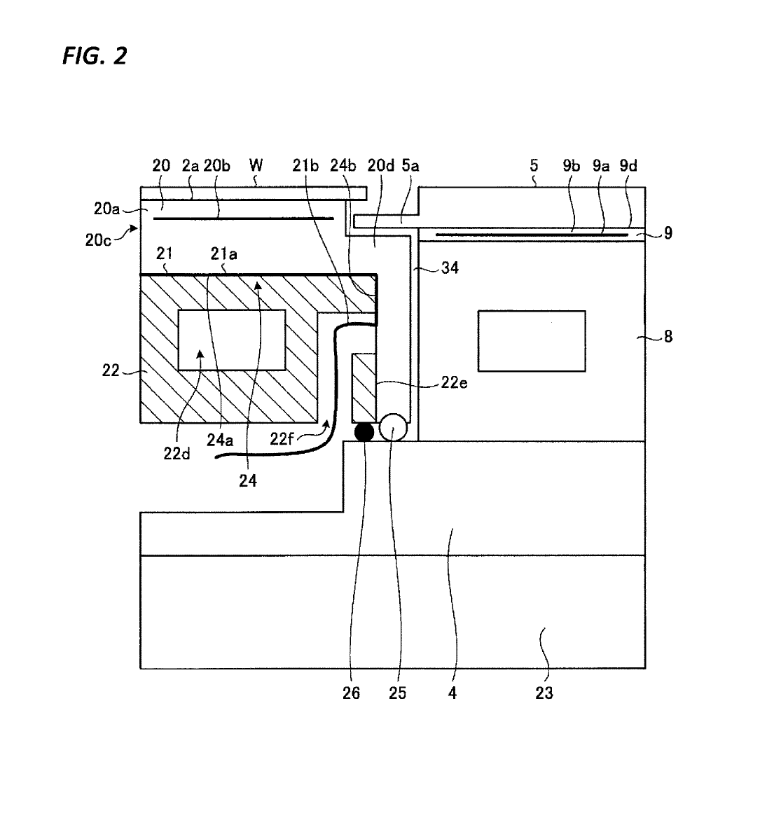

Next, descriptions will be made on the configuration of main parts of the first placing table 2 and the second placing table 7. FIG. 2 is a schematic cross-sectional view illustrating an example of a configuration of a main part of the first and second placing tables.

The first placing table 2 includes a first member 20, a sheet member 21, and a second member 22.

The first member 20 is made of an insulator 20a, for example, a ceramic, and formed in a cylindrical shape with its bottom surfaces facing upward and downward. The first member 20 has an upper bottom surface served as the placing surface 2a on which the wafer W is placed. Further, the first member 20 includes a flange portion 20d of which the lower portion protrudes outward in the radial direction from the upper portion which is the placing surface 2a side in a flat portion 20c that constitutes the upper bottom surface. That is, an outer diameter of the flat portion 20c of the first member 20 differs depending on the position of the side surface, and the lower portion is formed to be protruded outward in the radial direction than the upper portion. The first member 20 is provided with an electrode 20b inside the insulator 20a above the flat portion 20c. The electrode 20b of the first member 20 is supplied with a power via a power supply mechanism (not illustrated). As a power supply mechanism to the electrode 20b, a power supply wiring may be formed inside the first member 20, a power supply wiring may be formed in the sheet member 21, or a power supply wiring may be formed in the second member 22 by forming a through hole.

The first member 20 includes a recessed portion 24 in a range corresponding to the placing surface 2a in the lower bottom surface of the first member 20. That is, the first member 20 includes the recessed portion 24 which is recessed in a range corresponding to the placing surface 2a on the back surface side with respect to the placing surface 2a. The recessed portion 24 includes a bottom surface 24a which is in parallel with the placing surface 2a and is sized to be approximately the same size as the wafer W or slightly larger than the wafer W, and a side surface 24b surrounding the bottom surface 24a. The sheet member 21 is disposed in the recessed portion 24.

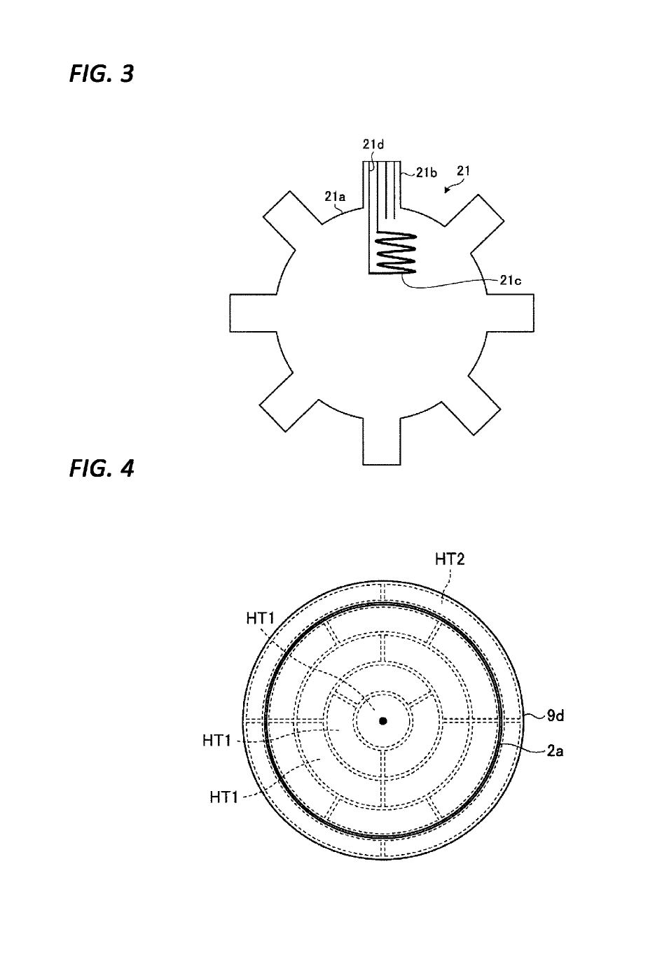

FIG. 3 is a schematic plan view illustrating an example of a configuration of a main part of a sheet member. The sheet member 21 is formed in a sheet shape using, for example, an organic material such as polyimide, and includes circular portions 21a formed in a circular shape and wiring portions 21b extending from the circular portions 21a around the circular portions 21a. Eight wiring portions 21b are provided radially from the circular portions 21a. The sheet member 21 may be formed using any materials as long as the materials have heat resistance, flame retardancy, and voltage resistance. For example, instead of polyimide, polyamide, polyester, Teflon (registered trademark), liquid crystal polymer, or the like may be used.

The circular portion 21a is provided with a heater 21c therein and is formed to have a size corresponding to the placing surface 2a inside the recessed portion 24. For example, the circular portion 21a is formed to have a size corresponding to the bottom surface 24a of the recessed portion 24. The wiring portion 21b is provided with a lead wiring 21d therein.

Such a sheet member 21 may be easily produced by flexible printed circuits (FPC). A film of the FPC is called a base film and is mainly made of, for example, polyimide. The FPC, including wiring, may be thin and flexible so as to be bent freely. For example, the FPC includes a wiring on an insulating film made of the polyimide or the like, by changing the resistivity depending on the cross-sectional area such as thickness, so that the sheet member 21 including the heater 21c and the lead wiring 21d may be produced. For example, the sheet member 21 may be formed using the FPC and a maximum current flowing through the wiring such as the lead wiring 21d may be 0.3 A. In this case, the wiring such as the lead wiring 21d is formed to have a thickness of 18 μm a width of 1 mm so as not to generate heat. The heater 21c is formed to have a thickness of 9 μm and a width as small as possible, and has higher resistance than that of the lead wiring 21d such that the heater 21c generates heat as resistance heating. When the resistivity is changed, not only the cross-sectional area of the wiring, but also a wiring material may be changed, or the material and the cross-sectional area may be changed in combination.

The heater 21c may be provided solely on the entire surface of the region of the placing surface 2a or may be provided individually for each divided region of the placing surface 2a. That is, the circular portion 21a of the sheet member may be provided with a plurality of heaters 21c individually for each divided region of the placing surface 2a. For example, the placing surface 2a of the first placing table 2 may be divided into a plurality of regions according to the distance from the center, and the heaters 21c may extend annularly to surround the center of the first placing table 2 in the respective regions. Alternatively, the sheet member 21 may include a heater for heating the central region and a heater extending annularly to surround the central region. Further, a region extended annularly to surround the center of the placing surface 2a may be divided into a plurality of regions according to the direction from the center, and a heater 6c may be provided in each region. Even in a case where a plurality of heaters 21c are provided, the sheet member 21 are provided with a plurality of wiring portions 21b so that the lead wiring 21d for supplying power to each of the heaters 21c may be easily provided.

FIG. 4 is a schematic plan view illustrating an example of a region on which a heater is disposed. FIG. 4 is a plan view of the first placing table 2 and the second placing table 7 when viewed from the top. In FIG. 4, the placing surface 2a of the first placing table 2 is illustrated in a disk shape. The placing surface 2a is divided into a plurality of regions HT1 according to the distance and direction from the center, and the heater 6c is provided individually in each of the regions HT1. Therefore, the plasma processing apparatus 10 may control the temperature of the wafer W for each of the regions HT1.

The circular portion 21a of the sheet member 21 may be provided with regions where the heaters 21c are provided so as to overlap each other.

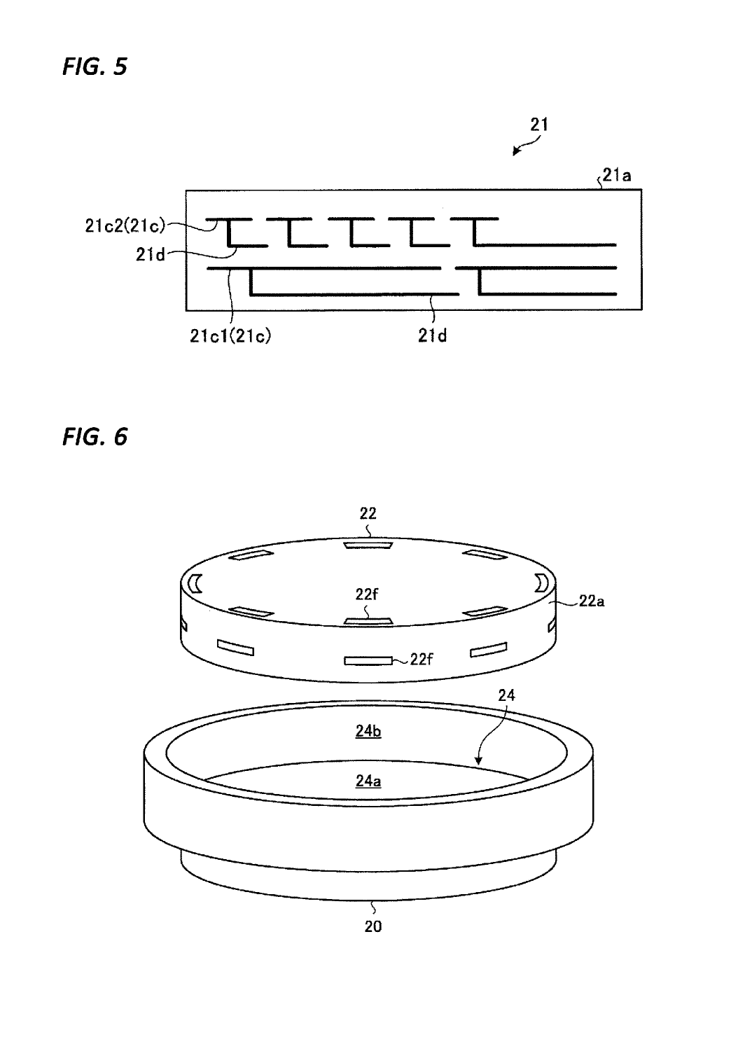

FIG. 5 is a schematic plan view illustrating an example of a cross-section of a sheet member. FIG. 5 illustrates a case where, as a heater 21c, a base heater 21c1 that warms a relatively wide region and a trim heater 21c2 that warms a region narrower than the base heater 21c1 are provided to be overlapped. In such a sheet member 21, the base heater 21c1 stably warms a relatively wide region to a temperature which is the basis of the temperature control and the trim heater 21c2 individually adjusts the temperatures of the respective regions.

As illustrated in FIG. 2, the sheet member 21 is disposed in the recessed portion 24 such that the circular portion 21a provided with the heater 21c is positioned in the region corresponding to the placing surface 2a inside the recessed portion 24, the wiring portion 21b provided with the lead wiring 21d is positioned on the side surface 24b of the recessed portion 24.

The second member 22 is fitted into the recessed portion 24 where the sheet member 21 is disposed. The second member 22 includes a coolant flow path 22d formed therein.

FIG. 6 is a schematic perspective view illustrating an example of a configuration of a main part of a second member. FIG. 6 illustrates a state before fitting of the second member 22 and the first member 20. Further, in an example of FIG. 6, the placing surface 2a of the first member 20 is a lower side, and the up and down directions are reversed from those of FIG. 2. That is, as compared with FIGS. 1 and 2, the top and bottom are opposite (upside down).

The second member 22 is formed in a cylindrical shape with the same size as or slightly smaller size than the recessed portion 24 by, for example, a conductive material such as aluminum. Further, the second member 22 is provided with through holes 22f communicating to the back surface side with respect to the recessed portion 24 on a surface 22e facing the side surface 24b of the recessed portion 24. The through holes 22f are provided at positions where the wiring portions 21b of the sheet member 21 are provided. Eight through holes 22f are provided at regular intervals in the example of FIG. 6.

As illustrated in FIG. 2, in the sheet member 21, the wiring portion 21b passes through the through hole 22f of the second member 22 and one end of the wiring portion 21b is extended to the lower side of the second member 22. In the lower side of the second member 22, a power supply terminal (not illustrated) is provided and the end of the wiring portion 21b is connected to the power supply terminal. In the sheet member 21, power from the heater power supply is supplied to the power supply terminal under the control of the controller 90. The placing surface 2a is heated and controlled by the heaters 21c of the sheet member 21.

The peripheral of the first placing table 2 is supported by the RF plate 4 in a state where the second member 22 is fitted into the first member 20, and an O-ring 25 is provided in a portion in contact with the RF plate 4. Therefore, the first placing table 2 may maintain vacuum in the processing space. Further, the first placing table 2 may suppress the plasma generated in the processing space from going around to the lower portion. Further, a metallic spiral ring 26 is provided inside the O-ring 25, whereby the second member 22 and the RF plate are electrically connected.

As described above, the first placing table 2 is provided with the first member 20, which is formed of, for example, an insulator 20a such as ceramic, on the outer peripheral surface. Therefore, the sheet member 21 or the second member 22 may be protected from the plasma.

The second placing table 7 includes a base 8 and a focus ring heater 9. The focus ring heater 9 is attached to the base through an insulating layer (not illustrated). The upper surface of the focus ring heater 9 serves as a placing surface 9d on which the focus ring 5 is placed. The upper surface of the focus ring heater 9 may be provided with, for example, a sheet member having high thermal conductivity.

The height of the second placing table 7 is appropriately adjusted such that the heat transfer or the RF power to the wafer W and the heat transfer or the RF power to the focus ring 5 coincide with each other. That is, FIG. 2 illustrates a case where the height of the placing surface 2a of the first placing table 2 and the height of the placing surface 9d of the second placing table 7 do not coincide with each other, but both heights may coincide with each other.

The focus ring 5 is an annular member and is provided to be coaxial with the second placing table 7. On the inner side surface of the focus ring 5, a convex portion 5a is formed to protrude inward in the radial direction. That is, the inner diameter of the focus ring 5 differs depending on the position of the inner side surface. For example, an inner diameter of a portion where the convex portion 5a of the focus ring 5 is not formed is larger than the outer diameter of the wafer W. Meanwhile, an inner diameter of a portion where the convex portion 5a of the focus ring 5 is not formed is larger than an outer diameter of a portion where the flange portion 20d of the first member 20 is not formed.

The focus ring 5 is arranged on the second placing table 7 such that the convex portion 5a is separated from the upper surface of the flange 20d of the first member 20 and also separated from the side surface of the flat portion 20c of the first member 20. That is, a gap is formed between the lower surface of the convex portion 5a of the focus ring 5 and the upper surface of the flange portion 20d. Further, a gap is formed between the side surface of the convex portion 5a of the focus ring 5 and the side surface on which the flange portion 20d of the flat portion 20c is not formed. The convex portion 5a of the focus ring 5 is positioned above a gap 34 between the first placing table 2 and the second placing table 7. That is, when viewed from a direction orthogonal to the placing surface 2a, the convex portion 5a exists at a position overlapping the gap 34 and covers the gap 34. Therefore, it is possible to suppress the plasma from entering the gap 34 between the first placing table 2 and the second placing table 7.

In the focus ring 9, a heater 9a is provided inside the insulator 9b. The heater 9a has an annular shape that is coaxial with the base 8. The heater 9a may be provided solely on the entire surface of the region of the placing surface 9d or may be provided individually for each divided region of the placing surface 9d. That is, a plurality of heaters 9a may be provided individually for respective divided regions of the placing surface 9d. For example, the placing surface 9d of the second placing table 7 may be divided into a plurality of regions according to the distance from the center of the second placing table 7, and the heater 9a may be provided for each region. For example, in FIG. 4, the placing surface 9d of the second placing table 7 is illustrated in a disk shape around the placing surface 2a of the first placing table 2. The placing surface 9d is divided into a plurality of regions HT2 according to the direction from the center, and the heater 9a is provided individually in each of the regions HT2. The heater 9s is connected to the power supply terminal via a power supply mechanism (not illustrated). As the power supply mechanism for the heater 9a, a wiring for power supply may be formed on the peripheral portion of the base 8, or a wiring for power supply may be formed by forming a through hole in the base 8. The focus ring heater 9 is supplied with power from the heater power supply under the control of the controller 90. The placing surface 9d is heated and controlled by the heater 9a of the focus ring heater 9. Therefore, the plasma processing apparatus 10 may control the temperature of the focus ring 5 for each of the regions HT2.

[Action and Effect]

Next, descriptions will be made on an action and an effect of a plasma processing apparatus 10 according to the present embodiment. In a plasma processing (e.g., etching), in order to implement the uniformity of the in-plane processing precision of the wafer W, it is required to adjust not only the temperature of the wafer W but also the temperature of the focus ring 5 provided in the peripheral region of the wafer W.

Therefore, in the plasma processing apparatus 10, it is considered that the first placing table 2 on which the wafer W is placed and the second placing table 7 on which the focus ring 5 is placed are provided separately from each other so as to suppress the movement of heat. Therefore, the plasma processing apparatus 10 may individually adjust not only the temperature of the wafer W but also the temperature of the focus ring 5. For example, the plasma processing apparatus 10 may set the set temperature of the focus ring 5 in a higher temperature range compared with the set temperature of the wafer W. Therefore, the plasma processing apparatus 10 may implement the uniformity of the in-plane processing precision of the wafer W.

Further, in the plasma processing apparatus 10, the first placing table 2 is constituted by the first member 20, the sheet member 21, and the second member 22. The first member 20 includes the recessed portion 24 in a range corresponding to the placing surface 2a on the back surface side with respect to the placing surface 2a on which the wafer W is placed. The sheet member 21 is formed in a sheet shape, and provided with a heater 21c and a lead wiring 21d for supplying a power to the heater 21c. In the sheet member 21, the heater 21c is positioned in the region corresponding to the placing surface 2a inside the recessed portion 24, and the lead wiring 21d is disposed in the recessed portion 24 so as to be positioned on the side surface 24b of the recessed portion 24. The second member 22 is fitted into the recessed portion 24 where the sheet member 21 is disposed.

Here, for example, in a case where a configuration is used in which a through hole is formed in the first placing table 2 to supply power to the heater 21c, the portion where the through hole is formed in the placing surface 2a becomes a singular point where heat conduction is partially deteriorated and the uniformity of heat decreases. Therefore, non-uniformity is likely to occur in the temperature distribution in the circumferential direction of the wafer W, and the in-plane uniformity of the plasma processing on the wafer W decreases.

Meanwhile, in the plasma processing apparatus 10, the recessed portion is formed in a range corresponding to the placing surface 2a of the first member 20 and the sheet member 21 disposed in the recessed portion 24 is connected with the power supply terminal on the bask surface side of the second member 22. As a result, the plasma processing apparatus 10 may supply power to the heater 21c without forming a through hole in the first placing table 2. Thus, it is possible to suppress decrease in the in-plane uniformity of the plasma processing on the wafer W. Further, in the plasma processing apparatus 10, it is possible to reduce the width in the radial direction of the flange portion 20d on which the wiring required to supply power to the heater 21c is disposed, and it is possible to reduce the size in the radial direction of the first placing table 2. As a result, in the plasma processing apparatus 10, the overlapping portion between the focus ring 5 and the flange portion 20d may be reduced. Thus, it is possible to suppress occurrence of non-uniformity in the temperature distribution of the focus ring 5. In addition, it is possible to suppress deterioration in the in-plane uniformity of the plasma processing on the wafer W.

Further, the second member 22 is provided with through holes 22f communicating to the back surface side with respect to the recessed portion 24 on a surface 22e facing the side surface 24b of the recessed portion 24. The sheet member is provided with a heater 21c and includes circular portions 21a formed in a size of a region corresponding to the placing surface 2a inside the recessed portion 24, and wiring portions 21b in which a lead wiring 21d is provided and which are extended from the circular portions 21a. In the sheet member 21, the wiring portion 21b is disposed so as to pass through the through hole 22f in the second member 22. Therefore, in the plasma processing apparatus 10, the wiring portion 21b may be easily disposed to the back surface side of the second member 22.

Further, in the plasma processing apparatus 10, the heater 9a is provided on the placing surface 9d on which the focus ring 5 of the second placing table 7 is placed. Therefore, the plasma processing apparatus 10 may individually adjust not only the temperature of the wafer W but also the temperature of the focus ring 5. Thus, it is possible to enhance the uniformity of the in-plane processing precision of the wafer W.

Further, in the plasma processing apparatus 10, the coolant flow path 22d is formed inside the second member 22. Since the plasma processing apparatus 10 may control the temperature of the wafer W by allowing the coolant to flow through the coolant flow path 22d, it is possible to improve the processing precision of the wafer W by the plasma processing.

As such, various embodiments have been described, but various modifications may be made without being limited to the embodiments described above. For example, the above-described plasma processing apparatus 10 is a capacitively coupled plasma processing apparatus 10, but the first placing table 2 may be employed in an arbitrary plasma processing apparatus 10. For example, the plasma processing apparatus 10 may be any type of plasma processing apparatus 10, such as an inductively coupled plasma processing apparatus 10 or a plasma processing apparatus 10 for exciting a gas with surface waves (e.g., microwaves).

Further, in the above-described plasma processing apparatus 10, as an example, the description has been made on the case where the through hole 22f communicating to the back surface side with respect to the recessed portion 24 is formed on the surface 22e of the second member 22 and the wiring portion 21b of the sheet member 21 is disposed so as to pass through the through hole 22f, but the present disclosure is not limited thereto. For example, a groove communicating to the back surface side with respect to the recessed portion 24 is formed on the surface 22e of the second member 22, and the wiring portion 21b of the sheet member 21 may be disposed so as to pass through the groove. In this case as well, in the plasma processing apparatus 10, the wiring portion 21b may be easily disposed to the back surface side of the second member 22.

Further, each of the above-described first member 20, sheet member 21, and second member may be configured by combining a plurality of parts. For example, the first member 20 may be configured by combining parts that constitutes the flat portion 20c and annular parts that constitute the side surface of the recessed portion 24.

Further, as an example, the description has been made on the case where the first member 20 has a function of an electrostatic chuck by providing the electrode 20b therein, but the present disclosure is not limited thereto. For example, the plasma processing apparatus 10 may be provided with an electrostatic chuck separately from the first member 20.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A plasma processing apparatus comprising:
a first member including a recessed portion in a range corresponding to a placing surface on a back surface side with respect to the placing surface on which a plasma processing target workpiece is placed;
a sheet member formed in a sheet shape, including a heater and a lead wiring that supplies power to the heater, and disposed in the recessed portion such that the heater is positioned in a region corresponding to a placing surface inside the recessed portion and the lead wiring is positioned on a side surface of the recessed portion; and
a second member fitted into the recessed portion in which the sheet member is disposed.

2. The plasma processing apparatus of claim 1, wherein the second member includes a groove or a through hole that communicates with a back surface side with respect to the recessed portion on a surface facing the side surface of the recessed portion,
the sheet member includes a heater portion provided with the heater and formed to have a size of a region corresponding to the placing surface inside the recessed portion and a wiring portion provided with the lead wiring and extended from the heater portion, and
the wiring portion is disposed so as to pass through the groove or the through hole of the second member.

3. The plasma processing apparatus of claim 1, further comprising:
a placing table on which a focus ring is placed along an outer peripheral surface of the first member,
wherein the first member is formed in a cylindrical shape with the placing surface as a bottom surface.

4. The plasma processing apparatus of claim 3, wherein the placing table is provided with a heater on a placing surface on which the focus ring is placed.

5. The plasma processing apparatus of claim 1, wherein the second member includes a coolant flow path formed therein.
